(19) United States
(12) Patent Application Publication
(10) Pub. No.: US 2016/0014931 A1
(43) Pub. Date: Jan. 14, 2016

(54) COOLING APPARATUS

(71) Applicant: Furukawa Electric Co., Ltd., Tokyo (JP)

(72) Inventor: Akira Hamakawa, Tokyo (JP)

(73) Assignee: Furukawa Electric Co., Ltd., Tokyo (JP)

(21) Appl. No.: 14/866,202

(22) Filed: Sep. 25, 2015

Related U.S. Application Data
(63) Continuation of application No. PCT/JP2014/058197, filed on Mar. 25, 2014.

(30) Foreign Application Priority Data
Mar. 27, 2013 (JP) 2013-067549

(51) Int. Cl. H05K 7/20

(52) U.S. Cl. CPC H05K 7/20336

(57) ABSTRACT

The purpose of this invention is to provide a liquid-cooled cooling apparatus including a heat pipe that allows a working fluid to be stably moved regardless of the magnitude of a temperature difference between a heat-dissipating portion and a condensing portion of the heat pipe. A heat sink (10) of a cooling apparatus includes a heat pipe (11), a heat-receiving member (12), and a heat-dissipating member (13). The heat pipe (11) has a wick (42) that is disposed in the inside of a container (41). The wick (42) has a structure having a capillary force of a wick (evaporation portion wick) (42a) of an evaporation portion (21) greater than a capillary force of a wick (condensing portion wick) (42b) of a condensing portion (22).

### TECHNICAL FIELD

The present invention relates to a cooling apparatus. More particularly, the present invention relates to a liquid-cooled cooling apparatus that cools components to be cooled, such as various electronic packages, used in the inside of electronic devices, such as an electronic computer, a workstation, and a personal computer.

### BACKGROUND ART

In recent years, since electronic components (components to be cooled) generating heat, such as semiconductor elements (CPU, GPU, and the like), are disposed on a substrate (or the like) in the inside of a housing such as an electronic computer, a workstation, or a personal computer, there has been a strong demand for a cooling technique that is used to efficiently cool the components to be cooled and achieves reduction in size and thickness. There is an air-cooled heat sink, which has been often used in related art, as one technique that cools components to be cooled.

The air-cooled heat sink in related art includes a heat-receiving portion and heat-dissipation fins, and cools the components to be cooled by sending air to the heat-dissipation fins. Further, there is also a heat sink that includes a heat pipe besides the heat-receiving portion and the heat-dissipation fins to disperse heat to the entire heat sink. The heat pipe is a container such as a metal pipe that is vacuum-degassed and hermetically sealed and where condensable fluid serving as working fluid is sealed. Furthermore, when a temperature difference is generated in the heat pipe, the heat pipe automatically operates, and a working fluid evaporated at a high-temperature portion (evaporation portion) flows to a low-temperature portion (condensing portion), radiates heat, and is condensed. Accordingly, the heat pipe transports heat as the latent heat of the working fluid.

However, since sufficient heat dissipation performance is not obtained in the air-cooled heat sink in the related art as the amount of heat to be generated is increased with the improvement of the performance of the components to be cooled such as semiconductor elements, the temperature of the components to be cooled cannot be sufficiently lowered. For this reason, there has been proposed an air-cooled heat sink that improves heat dissipation performance by increasing the surface area of heat-dissipation fins. Furthermore, there has also been proposed a cooling system in which a cooling fan is provided on an air-cooled heat sink to improve the heat dissipation performance by increasing the amount of air sent to heat-dissipation fins.

However, when the surface area of the heat-dissipation fins is increased for the improvement of heat dissipation performance, there is a problem in that the heat-dissipation fins occupy a large space. Further, when the rotational speed of the cooling fan is increased to increase the amount of air for the improvement of heat dissipation performance, there are problems in that noise caused by the sending of air is increased and power consumption is increased.

Accordingly, a liquid-cooled (water-cooled) cooling apparatus has been proposed as alternative means that solves the problems of the above-mentioned air-cooled heat sink in the related art (for example, Patent Documents 1, 2, and 3). There is a liquid-cooled cooling apparatus that includes a cold plate and a heat sink, as one example of the liquid-cooled cooling apparatus. The cold plate is a member for heat dissipation that takes in a liquid heat transport medium so that the temperature of the member is managed. Meanwhile, the liquid heat transport medium contains water, of which the temperature is managed by a circulation device or the like having a temperature control function, as a main ingredient. The heat sink is adapted so that one end portion of a heat pipe is thermally connected to components to be cooled and the other end portion of the heat pipe is thermally connected to the cold plate. Further, the liquid-cooled cooling apparatus in the related art is adapted to dissipate heat by transferring heat, which is generated from components to be cooled, to the cold plate through the heat sink.

That is, a space, which forms a flow passage for a working fluid, is formed in the inside of the heat pipe, and a working fluid stored in the space is subjected to phase change, such as evaporation or condensation, or movement. As a result, heat is transferred. The working fluid is evaporated in the evaporation portion of the heat pipe by the heat, which is generated from the components to be cooled and is transferred through the material of the container forming the heat pipe, and the vapor of the working fluid is moved to the condensing portion of the heat pipe. The vapor of the working fluid is condensed in the condensing portion by the wall surface of the heat pipe, which is cooled by the cold plate, and returns to a liquid-phase state again. When the working fluid is condensed, latent heat is released. The working fluid, which has returned to a liquid-phase state in this way, is moved (returns) to the evaporation portion again by a wick that is provided in the inside of the heat pipe and generates a capillary force. Heat is transferred by the phase change or the movement of the working fluid.

### CITATION LIST

### Patent Document

Patent Document 1: JP 5-256588 A

Patent Document 2: JP UM 6-50356 A

Patent Document 3: Japanese Registered Utility Model No. 3153906

### DISCLOSURE OF THE INVENTION

### Problem to be Solved by the Invention

However, since the condensing portion of the heat pipe is forcibly cooled by the cold plate in the liquid-cooled cooling apparatus in the related art, a constant temperature difference is always generated between the evaporation portion and the condensing portion. For this reason, since the viscosity of the working fluid in the condensing portion and near the condensing portion is larger than that in the air-cooled heat sink in the related art, it is difficult for the liquefied working fluid to return to the evaporation portion. As a result, in the evaporation portion, the amount of liquefied working fluid to be resupplied by a capillary force is smaller than the amount of the evaporated working fluid. For this reason, there is a problem in that the depletion (dry-out) of the working fluid occurs.

Accordingly, the invention has been made to solve the above-mentioned problems, and an object of the invention is to provide a liquid-cooled cooling apparatus including a heat pipe that allows a working fluid to be stably moved regardless of the magnitude of a temperature difference between a heat-dissipating portion and a condensing portion of the heat pipe.

### Means for Solving Problem

The following invention is provided to solve the above-mentioned problems in the related art.

A cooling apparatus according to a first aspect of the invention includes a cold plate and a heat sink. The heat sink includes: a heat-receiving member thermally connected to a component to be cooled; a heat-dissipating member thermally connected to a member for heat dissipation; and a heat pipe including a container having a cavity formed therein, a wick stored in the inside of the container and generating a capillary force, and a working fluid that is sealed in the cavity formed in the container. The heat pipe includes an evaporation portion having the heat-receiving member mounted thereon and a condensing portion having the heat-dissipating member mounted thereon, the wick stored in the container includes at least a groove structure that is provided on an inner wall of the container and has a structure having a capillary force of an evaporation portion wick stored in the container at the evaporation portion greater than a capillary force of a condensing portion wick stored in the container at the condensing portion, and the heat-dissipating member of the heat sink and the cold plate are thermally connected to each other.

According to this structure, when the capillary force of the wick (the evaporation portion wick) in the evaporation portion and near the evaporation portion of the heat pipe thermally connected to the component to be cooled through the heat-receiving member is increased, the working fluid is likely to be stagnant in the evaporation portion and near the evaporation portion. That is, the water retention characteristics for the working fluid in the evaporation portion and near the evaporation portion are improved. As a result, it is possible to prevent the occurrence of the depletion (dry-out) of the working fluid in the evaporation portion and near the evaporation portion.

Further, when the capillary force of the wick (the condensing portion wick) in the condensing portion and near the condensing portion of the heat pipe thermally connected to the cold plate through the heat-dissipating member is reduced, it is possible to prevent the occurrence of the depletion (dry-out) of the working fluid in the evaporation portion and near the evaporation portion.

According to a cooling apparatus of a second aspect of the invention, in the above-mentioned cooling apparatus according to the first aspect of the invention, the wick stored in the container has a structure having the amount of the evaporation portion wick greater than the amount of the condensing portion wick.

According to a cooling apparatus of a third aspect of the invention, when the structure of the evaporation portion wick and the structure of the condensing portion wick are the same type of structure of wick in the above-mentioned cooling apparatus according to the first aspect of the invention, the wick stored in the container has a structure having the area of the evaporation portion wick greater than the area of the condensing portion wick in a cross-section of the container perpendicular to a longitudinal direction of the container.

Here, the same type of structure of wick means that the structure of the evaporation portion wick and the structure of the condensing portion wick are the same structure (a groove structure, sintered metal, mesh-like metal, or the like) or the same composite body being a combination of a plurality of these structures.

According to a cooling apparatus of a fourth aspect of the invention, when the structure of the evaporation portion wick and the structure of the condensing portion wick are the same type of structure of wick and sintered metal or mesh-like metal is included in the same type of structure of wick in the above-mentioned cooling apparatus according to the first aspect of the invention, the wick stored in the container has a structure having a pore of the sintered metal or a mesh of the mesh-like metal of the evaporation portion wick in a cross-section of the container perpendicular to a longitudinal direction of the container smaller than that of the condensing portion wick.

According to this structures of the cooling apparatuses according to the second to fourth aspects of the invention, even though a temperature difference between the evaporation portion of the heat pipe, which is thermally connected to the component to be cooled through the heat-receiving member, and the condensing portion of the heat pipe, which is thermally connected to the cold plate through the heat-dissipating member, is large, high water retention characteristics of the working fluid in the evaporation portion and near the evaporation portion and high mobility of the working fluid, of which the viscosity is increased due to temperature reduction in the condensing portion and near the condensing portion, to the evaporation portion are obtained since the capillary force of the evaporation portion wick is greater than the capillary force of the condensing portion wick. Accordingly, it is possible to prevent the occurrence of the depletion (dry-out) of the working fluid that is caused by the lack of the amount of the working fluid to be resupplied in the evaporation portion and near the evaporation portion. As a result, the working fluid can be stably moved between the evaporation portion and the condensing portion.

According to a cooling apparatus of a fifth aspect of the invention, in the above-mentioned cooling apparatus according to any one of the first to fourth aspects of the invention, the wick is provided on an inner wall of the container and the container includes a space not having the wick and formed at a central portion of the cross-section of the container.

According to this structure, since the space formed in the inside of the container forms the flow passage (vapor flow passage) for the evaporated working fluid, a vapor flow can be rapidly moved to the condensing portion of the heat pipe from the evaporation portion of the heat pipe. That is, the maximum amount of heat to be transported can be increased.

According to a cooling apparatus of a sixth aspect of the invention, in the above-mentioned cooling apparatus according to any one of the first to fifth aspects of the invention, the structure of the wick is a groove structure, a composite body being a combination of a groove structure and sintered metal, a composite body being a combination of a groove structure and mesh-like metal, or a composite body being a combination of a groove structure, sintered metal and mesh-like metal.

According to a cooling apparatus of a seventh aspect of the invention, in the above-mentioned cooling apparatus according to the sixth aspect of the invention, only the structure of the evaporation portion wick is a composite body being a combination of the groove structure provided on the inner wall of the container and sintered metal or a composite body being a combination of the groove structure provided on the inner wall of the container and mesh-like metal.

According to this structure, the structure of the condensing portion wick is formed of a groove structure of which the capillary force is small, and the structure of the evaporation portion wick is formed of a composite body being a combination of a groove structure and sintered metal of which the capillary force is large or a composite body being a combination of a groove structure and mesh-like metal of which the capillary force is large. Accordingly, the capillary force of the evaporation portion wick is greater than the capillary force of the condensing portion wick. Further, it is possible to ensure a difference between the capillary force of the evaporation portion wick and the capillary force of the condensing portion wick that is sufficient to prevent the occurrence of the depletion (dry-out) of the working fluid caused by the lack of the amount of the working fluid to be resupplied in the evaporation portion and near the evaporation portion. As a result, the working fluid can be more stably moved between the evaporation portion and the condensing portion.

According to a cooling apparatus of an eighth aspect of the invention, in the above-mentioned cooling apparatus according to the sixth aspect of the invention, the structure of the wick of a portion of the container except for the condensing portion wick is a composite body being a combination of the groove structure provided on the inner wall of the container and sintered metal or a composite body being a combination of the groove structure provided on the inner wall of the container and mesh-like metal.

According to this structure, the structure of the condensing portion wick is formed of a groove structure of which the capillary force is small, and the structure of the wick of a portion of the container except for the condensing portion wick is formed of a composite body being a combination of the groove structure and sintered metal of which the capillary force is large or a composite body being a combination of the groove structure and mesh-like metal of which the capillary force is large. Accordingly, the capillary force of the evaporation portion wick is greater than the capillary force of the condensing portion wick. Further, it is possible to ensure a difference between the capillary force of the evaporation portion wick and the capillary force of the condensing portion wick that is sufficient to prevent the occurrence of the depletion (dry-out) of the working fluid caused by the lack of the amount of the working fluid to be resupplied in the evaporation portion and near the evaporation portion. As a result, the working fluid can be more stably moved between the evaporation portion and the condensing portion.

According to a cooling apparatus of a ninth aspect of the invention, in the above-mentioned cooling apparatus according to any one of the first to eighth aspects of the invention, the cross-sectional shape of the container of the heat pipe at the evaporation portion and the condensing portion is a D shape.

According to this structure, the contact area between the evaporation portion of the heat pipe and the heat-receiving member and the contact area between the condensing portion of the heat pipe and the heat-dissipating member can be increased. Further, it is possible to ensure a large vapor flow passage in the heat pipe. As a result, the maximum amount of heat to be transported can be increased.

According to a cooling apparatus of a tenth aspect of the invention, in the above-mentioned cooling apparatus according to any one of the first to ninth aspects of the invention, the groove structure providing on an inner wall of the container is that the height of a groove of the groove structure of the structure of the evaporation portion wick in the cross-section of the container perpendicular to the longitudinal direction of the container is greater than that of the structure of the condensing portion wick in the cross-section of the container perpendicular to the longitudinal direction of the container.

### Effect of the Invention

In the cooling apparatus according to the invention, when the capillary force of the wick (the evaporation portion wick) in the evaporation portion and near the evaporation portion of the heat pipe thermally connected to the components to be cooled through the heat-receiving member is increased, the working fluid is likely to be stagnant in the evaporation portion and near the evaporation portion. That is, the water retention characteristics for the working fluid in the evaporation portion and near the evaporation portion are improved. As a result, it is possible to prevent the occurrence of the depletion (dry-out) of the working fluid in the evaporation portion and near the evaporation portion.

Further, since the capillary force of the wick (the condensing portion wick) in the condensing portion and near the condensing portion of the heat pipe thermally connected to the cold plate through the heat-dissipating member is reduced, it is possible to prevent the occurrence of the depletion (dry-out) of the working fluid in the evaporation portion and near the evaporation portion.

Furthermore, in the cooling apparatus according to the invention, even though a temperature difference between the evaporation portion of the heat pipe, which is thermally connected to the components to be cooled through the heat-receiving member, and the condensing portion of the heat pipe, which is thermally connected to the cold plate through the heat-dissipating member, is large, high water retention characteristics of the working fluid in the evaporation portion and near the evaporation portion and high mobility of the working fluid, of which the viscosity is increased due to temperature reduction in the condensing portion and near the condensing portion, to the evaporation portion are obtained when the wick disposed in the container of the heat pipe has a structure that allows the capillary force of the evaporation portion wick to be greater than the capillary force of the condensing portion wick. Accordingly, it is possible to prevent the occurrence of the depletion (dry-out) of the working fluid that is caused by the lack of the amount of the working fluid to be resupplied in the evaporation portion and near the evaporation portion. As a result, the working fluid can be stably moved between the evaporation portion and the condensing portion.

Further, the cooling apparatus according to the invention can cool the heat pipe, which is thermally connected to the cold plate through the heat-dissipating member, by the cold plate, which is disposed at a position distant from the components to be cooled, without circulating the liquid heat transport medium to a position close to the components to be cooled, such as a semiconductor element, disposed on the substrate provided in the inside of a housing such as an electronic computer, a workstation, or a personal computer. Furthermore, the cooling apparatus can cool the components to be cooled that are thermally connected to the heat pipe through the heat-receiving member. As a result, it is possible to simplify a circulation path for the liquid heat transport medium and to reduce a risk caused by the leakage of water.

### BRIEF DESCRIPTION OF DRAWINGS

FIG. 1 is a schematic perspective view of a heat sink 10 that is an example of a heat sink provided in a cooling apparatus according to an embodiment of the invention;

FIGS. 2A and 2B are views illustrating the connection state among the heat sink 10, a component to be cooled, and a member for heat dissipation, FIG. 2A is a schematic perspective view of the connection state among the heat sink 10, the component to be cooled, and the member for heat dissipation, and FIG. 2B is an exploded perspective view of the connection state among the heat sink 10, the component to be cooled, and the member for heat dissipation;

FIGS. 3A to 3D are views illustrating the internal structure of a heat pipe 11 provided in the cooling apparatus according to the embodiment of the invention, FIG. 3A is a schematic cross-sectional view of a heat pipe 11a, which is an example of the heat pipe 11, taken in a longitudinal direction, FIG. 3B is a schematic cross-sectional view of the heat pipe 11a of FIG. 3A illustrating the cross-section perpendicular to the longitudinal direction and taken along line A-A, FIG. 3C is a schematic cross-sectional view of the heat pipe 11a of FIG. 3A illustrating the cross-section perpendicular to the longitudinal direction and taken along line C-C, and FIG. 3D is a schematic cross-sectional view of the heat pipe 11a of FIG. 3A illustrating the cross-section perpendicular to the longitudinal direction and taken along line B-B;

FIGS. 4A to 4D are views illustrating the internal structure of the heat pipe 11 provided in the cooling apparatus according to the embodiment of the invention, FIG. 4A is a schematic cross-sectional view of a heat pipe 11b, which is another example of the heat pipe 11, taken in a longitudinal direction, FIG. 4B is a schematic cross-sectional view of the heat pipe 11b of FIG. 4A illustrating the cross-section perpendicular to the longitudinal direction and taken along line A-A, FIG. 4C is a schematic cross-sectional view of the heat pipe 11b of FIG. 4A illustrating the cross-section perpendicular to the longitudinal direction and taken along line C-C, and FIG. 4D is a schematic cross-sectional view of the heat pipe 11b of FIG. 4A illustrating the cross-section perpendicular to the longitudinal direction and taken along line B-B; and

FIG. 5 is a schematic perspective view of a cooling apparatus 100 that is an example of the cooling apparatus according to the embodiment of the invention.

### MODE(S) FOR CARRYING OUT THE INVENTION

An embodiment of the invention will be described below in detail with reference to the drawings. Meanwhile, the description of this embodiment corresponds to an example of a cooling apparatus according to the invention, and is not limited thereto. The detailed structure and the like of a heat sink and the cooling apparatus of this embodiment can be appropriately modified without departing from the scope of the invention.

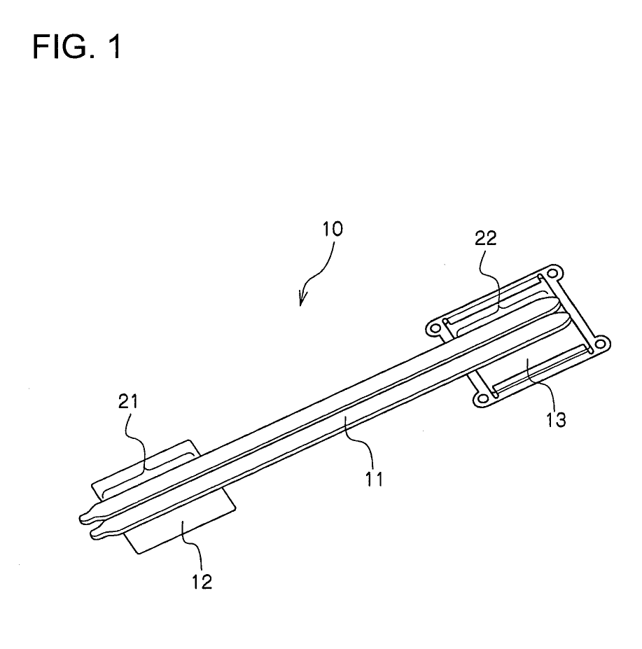

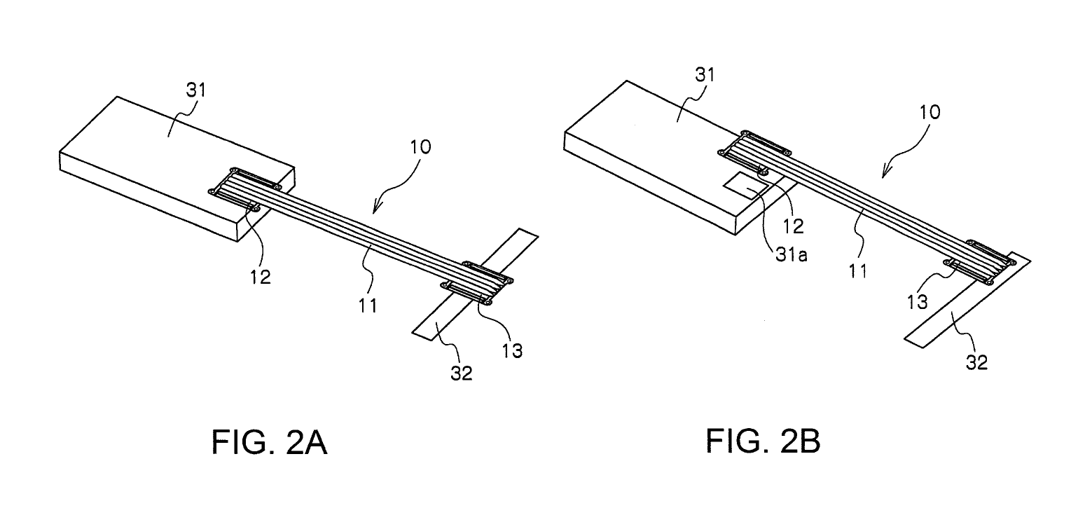

First, an example of a heat sink, which is provided in a cooling apparatus according to an embodiment of the invention, will be described. FIG. 1 is a schematic perspective view of a heat sink 10 that is an example of a heat sink provided in the cooling apparatus according to the embodiment of the invention. FIGS. 2A and 2B are views illustrating the connection state among the heat sink 10, a component to be cooled, and a member for heat dissipation. FIG. 2A is a schematic perspective view of the connection state among the heat sink 10, the component to be cooled, and the member for heat dissipation, and FIG. 2B is an exploded perspective view of the connection state among the heat sink 10, the component to be cooled, and the member for heat dissipation.

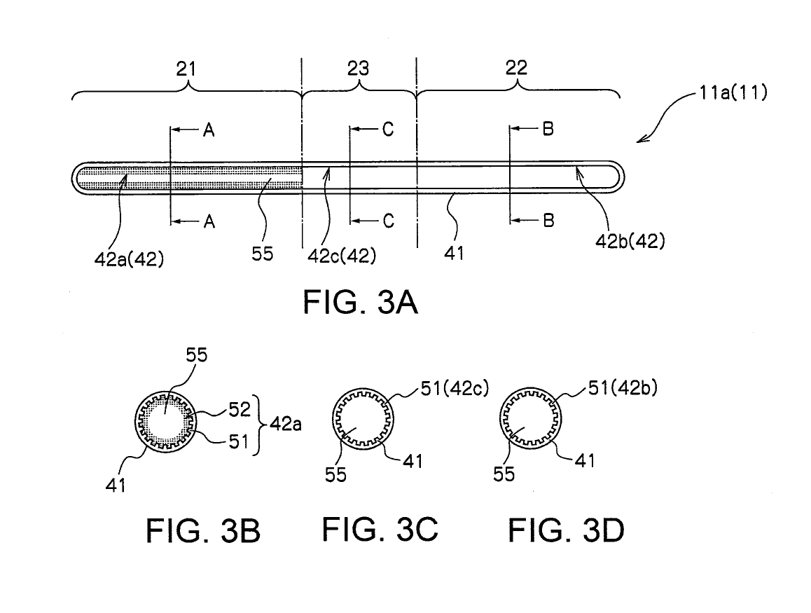

FIGS. 3A to 3D are views illustrating the internal structure of a heat pipe 11 provided in the cooling apparatus according to the embodiment of the invention. FIG. 3A is a schematic cross-sectional view of a heat pipe 11a, which is an example of the heat pipe, taken in a longitudinal direction. FIG. 3B is a schematic cross-sectional view of the heat pipe 11a of FIG. 3A illustrating the cross-section perpendicular to the longitudinal direction and taken along line A-A. FIG. 3C is a schematic cross-sectional view of the heat pipe 11a of FIG. 3A illustrating the cross-section perpendicular to the longitudinal direction and taken along line C-C. FIG. 3D is a schematic cross-sectional view of the heat pipe 11a of FIG. 3A illustrating the cross-section perpendicular to the longitudinal direction and taken along line B-B.

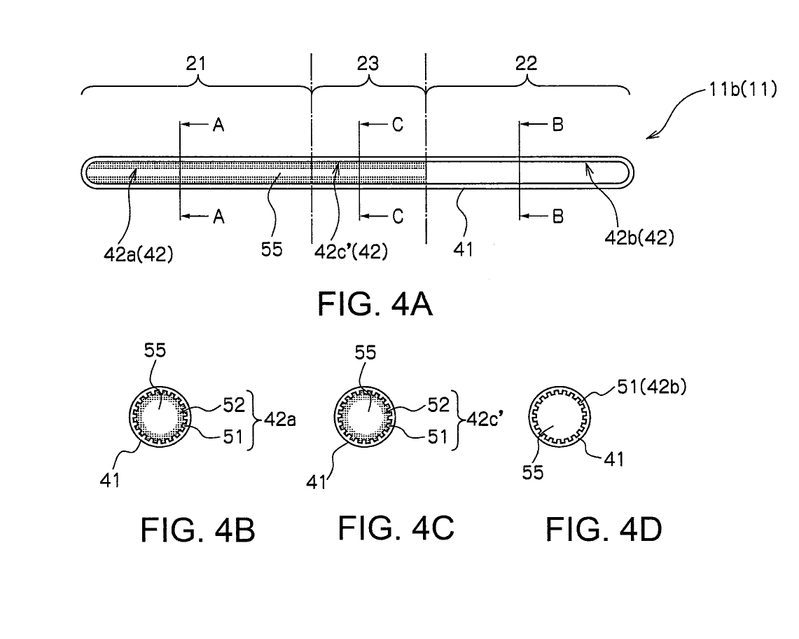

Further, FIGS. 4A to 4D are views illustrating the internal structure of the heat pipe 11 provided in the cooling apparatus according to the embodiment of the invention. FIG. 4A is a schematic cross-sectional view of a heat pipe 11b, which is another example of the heat pipe, taken in a longitudinal direction. FIG. 4B is a schematic cross-sectional view of the heat pipe 11b of FIG. 4A illustrating the cross-section perpendicular to the longitudinal direction and taken along line A-A. FIG. 4C is a schematic cross-sectional view of the heat pipe 11b of FIG. 4A illustrating the cross-section perpendicular to the longitudinal direction and taken along line C-C. FIG. 4D is a schematic cross-sectional view of the heat pipe 11b of FIG. 4A illustrating the cross-section perpendicular to the longitudinal direction and taken along line B-B.

As illustrated in FIGS. 1, 2A and 2B, the heat sink 10, which is an example of the heat sink provided in the cooling apparatus according to the embodiment of the invention, includes a heat pipe 11, a heat-receiving member 12, and a heat-dissipating member 13. The heat-receiving member 12 is thermally connected to an evaporation portion 21 provided near one end portion of the heat pipe 11, and the heat-dissipating member 13 is thermally connected to a condensing portion 22 provided near the other end portion of the heat pipe 11.

The heat-receiving member 12 is a member that is thermally connected to a component 31a to be cooled, and is formed of, for example, a metal plate or the like. The component 31a to be cooled is disposed on a substrate 31 that is provided in the inside of a housing such as an electronic computer, a workstation, a personal computer, or the like.

The connection configuration of the heat-receiving member 12, the heat pipe 11, and the component 31a to be cooled will be described. The evaporation portion 21 of the heat pipe 11 is disposed on one surface (the upper surface in FIGS. 2A and 2B) of the heat-receiving member 12 so that the heat-receiving member 12 and the evaporation portion 21 of the heat pipe 11 are thermally connected to each other. Further, the component 31a to be cooled is disposed on the other surface (the lower surface in FIGS. 2A and 2B) of the heat-receiving member 12 so that the heat-receiving member 12 and the component 31a to be cooled are thermally connected to each other. Furthermore, heat, which is generated from the component 31a to be cooled, is transferred to the evaporation portion 21 of the heat pipe 11 through the heat-receiving member 12.

The heat-dissipating member 13 is a member that is thermally connected to a member 32 for heat dissipation, and is formed of, for example, a metal plate or the like. The member 32 for heat dissipation is a cold plate, which takes in a liquid heat transport medium so that the temperature of the cold plate is managed, or the like. The liquid heat transport medium contains water, of which the temperature is managed by a circulation device or the like having a temperature control function, as a main ingredient.

The connection configuration of the heat-dissipating member 13, the heat pipe 11, and the member 32 for heat dissipation will be described. The condensing portion 22 of the heat pipe 11 is disposed on one surface (the upper surface in FIGS. 2A and 2B) of the heat-dissipating member 13 so that the heat-dissipating member 13 and the condensing portion 22 of the heat pipe 11 are thermally connected to each other. Further, the member 32 for heat dissipation is disposed on the other surface (the lower surface in FIGS. 2A and 2B) of the heat-dissipating member 13 so that the heat-dissipating member 13 and the member 32 for heat dissipation are thermally connected to each other. Furthermore, the member 32 for heat dissipation is adapted to cool the condensing portion 22 of the heat pipe 11 through the heat-dissipating member 13.

As illustrated in FIGS. 3A to 3D and FIGS. 4A to 4D, the heat pipe 11 (11a, 11b) provided in the cooling apparatus according to the embodiment of the invention includes a container 41 in which a cavity 55 is formed, a wick 42 (42a, 42b, 42c, 42c′) that is stored and disposed in the inside of the container 41 and generates a capillary force, and a working fluid (not illustrated) that is sealed in the cavity 55 formed in the container 41. The wick 42 is sealed in the container 41 together with the working fluid and the container 41 is hermetically sealed after the removal of air, so that the heat pipe 11 is formed.

As illustrated in FIGS. 3A to 3D and FIGS. 4A to 4D, the wick 42 is disposed in the inside of the container 41 of the heat pipe 11 (11a, 11b) that is an example of the heat pipe provided in the cooling apparatus according to the embodiment of the invention. The wick 42 is adapted so that a capillary force of the wick (evaporation portion wick) 42a of the evaporation portion 21 and a capillary force of the wick (condensing portion wick) 42b of the condensing portion 22 are different from each other.

Meanwhile, difference between the heat pipe 11a illustrated in FIGS. 3A to 3D and the heat pipe 11b illustrated in FIGS. 4A to 4D is difference between the structure of an intermediate wick 42c of the heat pipe 11a and the structure of an intermediate wick 42c′ of the heat pipe 11b, and the detail of the difference will be described below. Further, a portion of the heat pipe 11 (11a, 11b) between the evaporation portion 21 and the condensing portion 22 is called an intermediate portion 23, and the wick of the intermediate portion 23 is called an intermediate wick 42c or 42′.

Furthermore, in the heat pipe 11a illustrated in FIGS. 3A to 3D and the heat pipe 11b illustrated in FIGS. 4A to 4D, the evaporation portion wick 42a is described as the wick of the evaporation portion 21 and the condensing portion wick 42b is described as the wick of the condensing portion 22. However, the evaporation portion wick 42a may be a wick of a region that includes not only the evaporation portion 21 but also a portion of the heat pipe near the evaporation portion 21, that is, a region that is formed of the evaporation portion 21 and the portion of the heat pipe near the evaporation portion 21. Moreover, the condensing portion wick 42b may be a wick of a region that includes not only the condensing portion 22 but also a portion of the heat pipe near the condensing portion 22, that is, a region that is formed of the condensing portion 22 and the portion of the heat pipe near the condensing portion 22. In this case, each of the intermediate wicks 42c and 42′ is the wick 42 between the evaporation portion wick 42a and the condensing portion wick 42b.

Here, the wick is formed by providing wire mesh, sintered metal, a metal felt, or the like in the inside of the heat pipe. A capillary phenomenon can be caused in the working fluid that comes into contact with the wick. Accordingly, the working fluid can return. Further, the structure of the wick 42 may be any structure, and examples of the structure of the wick 42 include one structure among a groove structure, sintered metal, and mesh-like metal (mesh-like metal weaved using thin metallic wires) , and a composite body that is a combination of a plurality of different structures among a groove structure, sintered metal, and mesh-like metal. Furthermore, the structure each of the evaporation portion wick 42a and the condensing portion wick 42b only have to be formed of a structure in which the capillary force of the evaporation portion wick 42a and the capillary force of the condensing portion wick 42b are different from each other. Accordingly, the evaporation portion wick 42a and the condensing portion wick 42b may have different structures and may have the same structure.

Here, the combination of a plurality of different structures among a groove structure, sintered metal, and mesh-like metal is called the composite body, and the combination of a plurality of the same structures among a groove structure, sintered metal, and mesh-like metal is merely called a structure. For example, the combination of plural pieces of mesh-like metal is merely called mesh-like metal. Further, examples of a case in which the evaporation portion wick 42a and the condensing portion wick 42b have different structures and the capillary forces thereof are different from each other include a case in which the evaporation portion wick 42a is made of sintered metal and the condensing portion wick 42b is made of mesh-like metal. Furthermore, examples of a case in which the evaporation portion wick 42a and the condensing portion wick 42b have the same structure and the capillary forces thereof are different from each other include a case in which the evaporation portion wick 42a and the condensing portion wick 42b are made of mesh-like metal and the areas of the evaporation portion wick 42a and the condensing portion wick 42b in the cross-section of the container perpendicular to the longitudinal direction of the container 41 are different from each other and a case in which the evaporation portion wick 42a and the condensing portion wick 42b are made of mesh-like metal and the fineness of the mesh of the evaporation portion wick 42a is different from the fineness of the mesh of the condensing portion wick 42b.

As illustrated in FIGS. 2A and 2B, in the heat sink 10, heat generated from the component 31a to be cooled is transferred to the evaporation portion 21 of the heat pipe 11 through the heat-receiving member 12 of the heat sink 10. Further, the working fluid is evaporated in the evaporation portion 21 of the heat pipe 11 by the heat, and the vapor of the working fluid is moved to the condensing portion 22 of the heat pipe 11. Furthermore, the vapor of the working fluid is condensed in the condensing portion 22 by the wall surface of the heat pipe 11 that is cooled by the member 32 for heat dissipation (a cold plate or the like) through the heat-dissipating member 13 of the heat sink 10, and returns to a liquid-phase state again. When the working fluid is condensed, latent heat is released. The working fluid, which has returned to a liquid-phase state in this way, is moved (returns) to the evaporation portion again by the wick 42 that is provided in the inside of the heat pipe 11 and generates a capillary force. Heat is transferred by the phase change or the movement of the working fluid.

When the capillary force of the evaporation portion wick 42a is increased in the heat sink 10 that is an example of the heat sink provided in the cooling apparatus according to the embodiment of the invention, the working fluid is likely to be stagnant in the evaporation portion 21 (and near the evaporation portion 21). That is, the water retention characteristics for the working fluid in the evaporation portion 21 (and near the evaporation portion 21) are improved. As a result, it is possible to prevent the occurrence of the depletion (dry-out) of the working fluid in the evaporation portion 21 (and near the evaporation portion 21). Meanwhile, the evaporation portion wick 42a is a wick of the evaporation portion 21 (a portion near the evaporation portion 21) of the heat pipe 11 that is thermally connected to the component 31a to be cooled through the heat-receiving member 12.

Further, when the capillary force of the condensing portion wick 42b is reduced, it is possible to prevent the occurrence of the depletion (dry-out) of the working fluid in the evaporation portion 21 and near the evaporation portion 21. Meanwhile, the condensing portion wick 42b is a wick of the condensing portion 22 (a portion near the condensing portion 22) of the heat pipe 11 that is thermally connected to the member 32 for heat dissipation (a cold plate or the like) through the heat-dissipating member 13.

It is preferable that the heat sink 10, which is an example of the heat sink provided in the cooling apparatus according to the embodiment of the invention, is further adapted so that the capillary force of the evaporation portion wick 42a is greater than the capillary force of the condensing portion wick 42b. Even though a temperature difference between the evaporation portion 21 of the heat pipe 11, which is thermally connected to the component 31a to be cooled through the heat-receiving member 12, and the condensing portion 22 of the heat pipe 11, which is thermally connected to the member 32 for heat dissipation (a cold plate or the like) through the heat-dissipating member 13, is large, high water retention characteristics of the working fluid in the evaporation portion 21 (and near the evaporation portion 21) and high mobility of the working fluid, of which the viscosity is increased due to temperature reduction in the condensing portion 22 (and near the condensing portion 22), to the evaporation portion 21 are obtained when the capillary force of the evaporation portion wick 42a is greater than the capillary force of the condensing portion wick 42b in the wick 42 disposed in the inside of the container 41 of the heat pipe 11. Accordingly, it is possible to prevent the occurrence of the depletion (dry-out) of the working fluid that is caused by the lack of the amount of the working fluid to be resupplied in the evaporation portion 21 (and near the evaporation portion 21). As a result, the working fluid can be stably moved between the evaporation portion 21 and the condensing portion 22.

Further, it is preferable that a space, which forms a flow passage (vapor flow passage) for the evaporated working fluid and in which the wick 42 is not present, is formed at the central portion of the cross-section of the container 41 of the heat pipe 11 of the heat sink 10 that is an example of the heat sink provided in the cooling apparatus according to the embodiment of the invention. A vapor flow can be rapidly moved to the condensing portion 22 from the evaporation portion 21, through the space formed in the container 41. That is, the maximum amount of heat to be transported can be increased.

Examples of a structure in which the capillary force of the evaporation portion wick 42a is greater than the capillary force of the condensing portion wick 42b include a structure illustrated in FIGS. 3A to 3D in which the structure of each of the condensing portion wick 42b and the intermediate wick 42c is formed of a groove structure and only the structure of the evaporation portion wick 42a is formed of a composite body that is a combination of a groove structure and sintered metal. Furthermore, examples of a structure in which the capillary force of the evaporation portion wick 42a is greater than the capillary force of the condensing portion wick 42b include a structure illustrated in FIGS. 4A to 4D in which the structure of the condensing portion wick 42b is formed of a groove structure, and the structure of each of the evaporation portion wick 42a and the intermediate wick 42c′ is formed of a composite body that is a combination of a groove structure and sintered metal.

Moreover, an example in which the amount of the evaporation portion wick 42a is greater than the amount of the condensing portion wick 42b may be provided as one structure in which the capillary force of the evaporation portion wick 42a is greater than the capillary force of the condensing portion wick 42b.

Further, specifically, examples (Examples 1 to 5) in which the structure of the evaporation portion wick 42a (Structure 1) and the structure of the condensing portion wick 42b (Structure 2) are combined with each other as described below may be provided as other examples of a structure in which the capillary force of the evaporation portion wick 42a is greater than the capillary force of the condensing portion wick 42b.

### EXAMPLE 1

Each of both (Structure 1) and (Structure 2) includes a groove structure as a wick in the container 41 and the area of a portion of (Structure 1), which includes the groove structure, in the cross-section of the container perpendicular to the longitudinal direction of the container 41 is greater than that of (Structure 2) in the cross-section of the container perpendicular to the longitudinal direction of the container 41.

### EXAMPLE 2

Each of both (Structure 1) and (Structure 2) includes a groove structure as a wick in the container 41 and the height of a groove of the groove structure of (Structure 1) in the cross-section of the container perpendicular to the longitudinal direction of the container 41 is greater than that of (Structure 2) in the cross-section of the container perpendicular to the longitudinal direction of the container 41.

### EXAMPLE 3

Each of both (Structure 1) and (Structure 2) includes sintered metal or mesh-like metal as a wick in the container 41 and the area of a portion of (Structure 1), which includes the sintered metal or the mesh-like metal, in the cross-section of the container perpendicular to the longitudinal direction of the container 41 is greater than that of (Structure 2) in the cross-section of the container perpendicular to the longitudinal direction of the container 41.

### EXAMPLE 4

Each of both (Structure 1) and (Structure 2) includes sintered metal or mesh-like metal as a wick in the container 41 and the pore of the sintered metal or the mesh of the mesh-like metal of (Structure 1) in the cross-section of the container perpendicular to the longitudinal direction of the container 41 is smaller than that of (Structure 2) in the cross-section of the container perpendicular to the longitudinal direction of the container 41.

### EXAMPLE 5

(Structure 1) includes sintered metal in addition to a groove structure as a wick in the container 41, and (Structure 2) includes a groove structure as a wick in the container 41. The groove structures of (Structure 1) and (Structure 2) have the same shape. Since (Structure 1) includes the sintered metal, the capillary force of the evaporation portion wick 42a is greater than the capillary force of the condensing portion wick 42b.

In the internal structure of the heat pipe 11a that is illustrated in FIGS. 3A to 3D and is an example of the heat pipe 11, a groove structure is provided on the entire inner wall of the container 41 of the heat pipe 11a. Further, a wick made of sintered metal is provided on a portion of the groove structure that is provided on the inner wall of the container 41 in the evaporation portion 21 (and near the evaporation portion 21). That is, the structure of each of the condensing portion wick 42b and the intermediate wick 42c is formed of a wick 51 having a groove structure of which the capillary force is small, and the structure of the evaporation portion wick 42a is formed of a composite body that is a combination of the wick 51 having a groove structure and a wick 52 made of sintered metal of which the capillary force is large. Due to the internal structure of the heat pipe 11a, the capillary force of the evaporation portion wick 42a is greater than the capillary force of the condensing portion wick 42b. Furthermore, it is possible to ensure a difference between the capillary force of the evaporation portion wick 42a and the capillary force of the condensing portion wick 42b that is sufficient to prevent the occurrence of the depletion (dry-out) of the working fluid caused by the lack of the amount of the working fluid to be resupplied in the evaporation portion 21 and near the evaporation portion 21. As a result, the working fluid can be more stably moved between the evaporation portion 21 and the condensing portion 22.

In the internal structure of the heat pipe 11b that is illustrated in FIGS. 4A to 4D and is an example of the heat pipe 11, a groove structure is provided on the entire inner wall of the container 41 of the heat pipe 11b. Further, a wick made of sintered metal is provided on a portion of the groove structure that is provided on the inner wall of the container 41 except for the condensing portion 22 (and a portion near the condensing portion 22). That is, the structure of the condensing portion wick 42b is formed of a wick 51 having a groove structure of which the capillary force is small, and the structure of each of the evaporation portion wick 42a and the intermediate wick 42c′ is formed of a composite body that is a combination of the wick 51 having a groove structure and a wick 52 made of sintered metal of which the capillary force is large. Due to the internal structure of the heat pipe 11b, the capillary force of the evaporation portion wick 42a is greater than the capillary force of the condensing portion wick 42b. Furthermore, it is possible to ensure a difference between the capillary force of the evaporation portion wick 42a and the capillary force of the condensing portion wick 42b that is sufficient to prevent the occurrence of the depletion (dry-out) of the working fluid caused by the lack of the amount of the working fluid to be resupplied in the evaporation portion 21 and near the evaporation portion 21. As a result, the working fluid can be more stably moved between the evaporation portion 21 and the condensing portion 22.

Further, in the heat pipe 11a illustrated in FIGS. 3A to 3D and the heat pipe 11b illustrated in FIGS. 4A to 4D, the evaporation portion wicks 42a, the condensing portion wicks 42b, and the intermediate wicks 42c and 42c′ are provided on the inner walls of the containers 41 of the heat pipes 11a and 11b. Furthermore, a space 55, which forms a flow passage (vapor flow passage) for the evaporated working fluid and in which the wick is not present, is formed at the central portion of the cross-section of the container 41. Since the space 55 forms the flow passage (vapor flow passage) for the evaporated working fluid, a vapor flow can be rapidly moved to the condensing portion of the heat pipe from the evaporation portion of the heat pipe. That is, the maximum amount of heat to be transported can be increased.

It is possible to form the structure of the wick 42, which is provided in the inside of the container 41 of the heat pipe 11a illustrated in FIGS. 3A to 3D, for example, by sintering metal powder on the wick 51 having a groove structure of the evaporation portion 21 of the heat pipe 11a to form sintered metal after providing the wick 51 having a groove structure on the entire inner wall of the container 41. Further, it is possible to form the structure of the wick 42, which is provided in the inside of the container 41 of the heat pipe 11b illustrated in FIGS. 4A to 4D, for example, by sintering metal powder on the wick 51 having a groove structure of the evaporation portion 21 and the intermediate portion 23 of the heat pipe 11b to form sintered metal after providing the wick 51 having a groove structure on the entire inner wall of the container 41.

In the internal structures of the heat pipe 11a illustrated in FIGS. 3A to 3D and the heat pipe 11b illustrated in FIGS. 4A to 4D, the structure of the evaporation portion wick 42a is a composite body that is a combination of the wick 51 having a groove structure and the wick 52 made of sintered metal, and the structure of the condensing portion wick 42b is the wick 51 having a groove structure. However, the structures are not limited thereto. For example, even when the structure of the evaporation portion wick 42a is formed of a composite body that is a combination of the wick having a groove structure and the wick made of mesh-like metal of which the capillary force is large and the structure of the condensing portion wick 42b is formed of the wick having a groove structure, the capillary force of the evaporation portion wick 42a is greater than the capillary force of the condensing portion wick 42b. Further, it is possible to ensure a difference between the capillary force of the evaporation portion wick 42a and the capillary force of the condensing portion wick 42b that is sufficient to prevent the occurrence of the depletion (dry-out) of the working fluid caused by the lack of the amount of the working fluid to be resupplied in the evaporation portion 21 and near the evaporation portion 21.

In each of the heat pipes 11 (11a and 11b), which are illustrated in FIGS. 3A to 3D and FIGS. 4A to 4D, of the heat sink 10 that an example of the heat sink provided in the cooling apparatus according to the embodiment of the invention, the cross-sectional shape of the container 41 of the heat pipe 11 is a round shape of which the diameter is substantially constant in the longitudinal direction. However, the cross-sectional shape of the container 41 is not limited to this shape, and only has to be a shape that allows the heat pipe to be thermally connected to the heat-receiving member 12 and the heat-dissipating member 13. Preferably, the cross-sectional shapes of the evaporation portion 21 and the condensing portion 22 are D shapes in which portions of the evaporation portion 21 and the condensing portion 22 coming into contact with the heat-receiving member 12 and the heat-dissipating member 13 are flat. When the cross-sectional shapes of the evaporation portion 21 and the condensing portion 22 in the cross-section of the container perpendicular to the longitudinal direction of the container 41 are D shapes as described above, the contact area between the evaporation portion 21 of the heat pipe 11 and the heat-receiving member 12 and the contact area between the condensing portion 22 of the heat pipe 11 and the heat-dissipating member 13 can be increased. Further, it is possible to ensure a large vapor flow passage in the heat pipe 11. As a result, the maximum amount of heat to be transported can be increased.

Meanwhile, the container 41 of the heat pipe 11, which is provided in the cooling apparatus according to the embodiment of the invention, is made of a heat conductive material. Preferably, the container 41 is made of an aluminum-based material or a copper-based material. Furthermore, it is preferable that water, Freon, or the like is used as the working fluid. A general joining technique may be used as welding for the end portion of the container. Preferably, the welding for the end portion of the container is laser welding, braze welding, or diffusion joining.

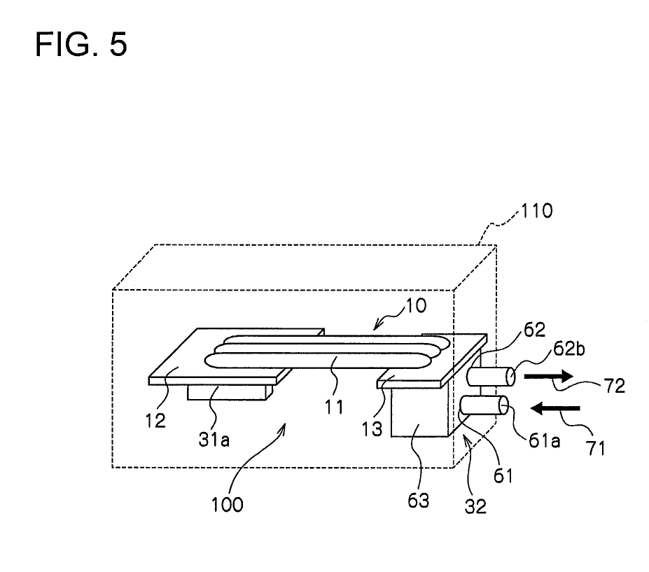

Next, an example of the cooling apparatus according to the embodiment of the invention, which includes the heat sink and the cold plate, will be described. FIG. 5 is a schematic perspective view of a cooling apparatus 100 that is an example of the cooling apparatus according to the embodiment of the invention. As illustrated in FIG. 5, the cooling apparatus 100, which is an example of the cooling apparatus according to the embodiment of the invention, includes the heat sink 10 described with reference to FIGS. 1 to 4D and a cold plate 32, and the heat-dissipating member 13 of the heat sink 10 and the cold plate 32 are thermally connected to each other.

As illustrated in FIG. 5, the cold plate 32 takes a liquid heat transport medium, which contains cooling water of which the temperature is managed as a main ingredient, in a body portion 63, which is made of a heat conductive material such as a copper block, from a water suction port 61. Further, latent heat, which is generated during the condensation of the working fluid and is released with the cooling of the heat pipe 11, is transferred to the liquid heat transport medium, and the liquid heat transport medium of which the temperature has risen due to the latent heat is discharged to the outside of the body portion 63 from a drain port 62. Accordingly, the temperature of the body portion 63 is managed.

Meanwhile, the cooling apparatus 100 is disposed in a housing 110, and the liquid heat transport medium of the cold plate 32 is taken in the body portion 63 from the outside of the housing 110 through a water suction nozzle 61a of which one end is positioned at the water suction port 61 of the body portion 63 as illustrated by an arrow 71. Furthermore, the liquid heat transport medium of the cold plate 32 is discharged to the outside of the housing 110 from the inside of the body portion 63 through a drain nozzle 62a of which one end is positioned at the drain port 62 of the body portion 63 as illustrated by an arrow 72. Meanwhile, an example in which the cooling apparatus 100 is disposed in the inside of the housing 110 has been described, but the cooling apparatus 100 may be disposed in the outside of the housing 110. It is possible to operate the cooling apparatus without introducing a coolant into the housing 110. Accordingly, it is possible to reduce the possibility of damage, which is caused by the leakage of a coolant, to a system on which a component to be cooled is mounted.

In the cooling apparatus 100, heat generated from the component 31a to be cooled is transferred to the evaporation portion 21 of the heat pipe 11 through the heat-receiving member 12 of the heat sink 10. Further, the working fluid is evaporated in the evaporation portion 21 of the heat pipe 11 by the heat, and the vapor of the working fluid is moved to the condensing portion 22 of the heat pipe 11. Furthermore, the vapor of the working fluid is condensed in the condensing portion 22 by the wall surface of the heat pipe 11 that is cooled by the cold plate 32 through the heat-dissipating member 13 of the heat sink 10, and returns to a liquid-phase state again. When the working fluid is condensed, latent heat is released. The released latent heat is transferred to the liquid heat transport medium, which is present in the cold plate 32, through the heat-dissipating member 13, and is released to the outside of the cold plate 32. The working fluid, which has returned to a liquid-phase state, is moved (returns) to the evaporation portion again by the wick 42 that is provided in the inside of the heat pipe 11 and generates a capillary force. Heat is transferred by the phase change or the movement of the working fluid.

As described above, the cooling apparatus 100, which is an example of the cooling apparatus according to the embodiment of the invention, can cool the heat pipe 11, which is thermally connected to the cold plate 32 through the heat-dissipating member 13, by the cold plate 32, which is disposed at a position distant from the component 31a to be cooled, without circulating the liquid heat transport medium to a position close to the component 31a to be cooled disposed on the substrate 31 provided in the housing 110. Further, the cooling apparatus can cool the component 31a to be cooled that is thermally connected to the heat pipe 11 through the heat-receiving member 12. For this reason, it is possible to simplify a circulation path for the liquid heat transport medium and to reduce a risk caused by the leakage of water.

Furthermore, even though a temperature difference between the evaporation portion 21 of the heat pipe 11, which is thermally connected to the component 31a to be cooled through the heat-receiving member 12, and the condensing portion 22 of the heat pipe 11, which is thermally connected to the cold plate 32 through the heat-dissipating member 13, is large, high water retention characteristics of the working fluid in the evaporation portion 21 and near the evaporation portion 21 and high mobility of the working fluid, of which the viscosity is increased due to temperature reduction in the condensing portion 22 (and near the condensing portion 22), to the evaporation portion 21 are obtained since the wick 42 disposed in the container 41 of the heat pipe 11 has a structure that allows the capillary force of the evaporation portion wick 42a to be greater than the capillary force of the condensing portion wick 42b. Accordingly, it is possible to prevent the occurrence of the depletion (dry-out) of the working fluid that is caused by the lack of the amount of the working fluid to be resupplied in the evaporation portion 21 and near the evaporation portion 21. As a result, the working fluid can be stably moved between the evaporation portion 21 and the condensing portion 22.

### EXPLANATIONS OF LETTERS OR NUMERALS

10: Heat Sink

11, 11a, 11b: Heat Pipe

12: Heat-Receiving Member

13: Heat-Dissipating Member

21: Evaporation Portion

22: Condensing Portion

23: Intermediate Portion

31: Substrate

31a: Component to be Cooled

32: Cold Plate (Member for Heat Dissipation)

41: Container

42: Wick

42a: Evaporation Portion Wick

42b: Condensing Portion Wick

42c, 42c′: Intermediate Wick

51: Wick Having Groove Structure

52: Wick Made of Sintered Metal

55: Space

100: Cooling Apparatus

1. A cooling apparatus comprising:
a cold plate; and
a heat sink,
wherein the heat sink includes
a heat-receiving member thermally connected to a component to be cooled,
a heat-dissipating member thermally connected to a member for heat dissipation, and
a heat pipe including a container having a cavity formed therein, a wick stored in the inside of the container and generating a capillary force, and a working fluid that is sealed in the cavity formed in the container,
the heat pipe includes an evaporation portion having the heat-receiving member mounted thereon and a condensing portion having the heat-dissipating member mounted thereon,
the wick stored in the container includes at least a groove structure that is provided on an inner wall of the container and has a structure having a capillary force of an evaporation portion wick stored in the container at the evaporation portion greater than a capillary force of a condensing portion wick stored in the container at the condensing portion, and
the heat-dissipating member of the heat sink and the cold plate are thermally connected to each other.

2. The cooling apparatus according to claim 1,
wherein the wick stored in the container has a structure having the amount of the evaporation portion wick greater than the amount of the condensing portion wick.

3. The cooling apparatus according to claim 1,
wherein when the structure of the evaporation portion wick and the structure of the condensing portion wick are the same type of structure of wick, the wick stored in the container has a structure having the area of the evaporation portion wick greater than the area of the condensing portion wick in a cross-section of the container perpendicular to a longitudinal direction of the container.

4. The cooling apparatus according to claim 1,
wherein when the structure of the evaporation portion wick and the structure of the condensing portion wick are the same type of structure of wick and sintered metal or mesh-like metal is included in the same type of structure of wick, the wick stored in the container has a structure having a pore of the sintered metal or a mesh of the mesh-like metal of the evaporation portion wick in a cross-section of the container perpendicular to a longitudinal direction of the container smaller than that of the condensing portion wick.

5. The cooling apparatus according to claim 1,
wherein the wick is provided on an inner wall of the container, and
the container includes a space not having the wick and formed at a central portion of the cross-section of the container.

6. The cooling apparatus according to claim 2,
wherein the wick is provided on an inner wall of the container, and
the container includes a space not having the wick and formed at a central portion of the cross-section of the container.

7. The cooling apparatus according to claim 3,
wherein the wick is provided on an inner wall of the container, and
the container includes a space not having the wick and formed at a central portion of the cross-section of the container.

8. The cooling apparatus according to claim 4,
wherein the wick is provided on an inner wall of the container, and
the container includes a space not having the wick and formed at a central portion of the cross-section of the container.

9. The cooling apparatus according to claim 1,
wherein the structure of the wick is a groove structure, a composite body being a combination of a groove structure and sintered metal, a composite body being a combination of a groove structure and mesh-like metal, or a composite body being a combination of a groove structure, sintered metal and mesh-like metal.

10. The cooling apparatus according to claim 2,
wherein the structure of the wick is a groove structure, a composite body being a combination of a groove structure and sintered metal, a composite body being a combination of a groove structure and mesh-like metal, or a composite body being a combination of a groove structure, sintered metal and mesh-like metal.

11. The cooling apparatus according to claim 3,
wherein the structure of the wick is a groove structure, a composite body being a combination of a groove structure and sintered metal, a composite body being a combination of a groove structure and mesh-like metal, or a composite body being a combination of a groove structure, sintered metal and mesh-like metal.

12. The cooling apparatus according to claim 9,
wherein only the structure of the evaporation portion wick is a composite body being a combination of the groove structure provided on the inner wall of the container and sintered metal or a composite body being a combination of the groove structure provided on the inner wall of the container and mesh-like metal.

13. The cooling apparatus according to claim 10,
wherein only the structure of the evaporation portion wick is a composite body being a combination of the groove structure provided on the inner wall of the container and sintered metal or a composite body being a combination of the groove structure provided on the inner wall of the container and mesh-like metal.

14. The cooling apparatus according to claim 11,
wherein only the structure of the evaporation portion wick is a composite body being a combination of the groove structure provided on the inner wall of the container and sintered metal or a composite body being a combination of the groove structure provided on the inner wall of the container and mesh-like metal.

15. The cooling apparatus according to claim 9,
wherein the structure of the wick of a portion of the container except for the condensing portion wick is a composite body being a combination of the groove structure provided on the inner wall of the container and sintered metal or a composite body being a combination of the groove structure provided on the inner wall of the container and mesh-like metal.

16. The cooling apparatus according to claim 10,
wherein the structure of the wick of a portion of the container except for the condensing portion wick is a composite body being a combination of the groove structure provided on the inner wall of the container and sintered metal or a composite body being a combination of the groove structure provided on the inner wall of the container and mesh-like metal.

17. The cooling apparatus according to claim 11,
wherein the structure of the wick of a portion of the container except for the condensing portion wick is a composite body being a combination of the groove structure provided on the inner wall of the container and sintered metal or a composite body being a combination of the groove structure provided on the inner wall of the container and mesh-like metal.

18. The cooling apparatus according to claim 1,
wherein the cross-sectional shape of the container of the heat pipe at the evaporation portion and the condensing portion is a D shape.

19. The cooling apparatus according to claim 2,
wherein the cross-sectional shape of the container of the heat pipe at the evaporation portion and the condensing portion is a D shape.

20. The cooling apparatus according to claim 1,
wherein the groove structure providing on an inner wall of the container is that the height of a groove of the groove structure of the structure of the evaporation portion wick in the cross-section of the container perpendicular to the longitudinal direction of the container is greater than that of the structure of the condensing portion wick in the cross-section of the container perpendicular to the longitudinal direction of the container.
